(19) United States
(12) Patent Application Publication
(10) Pub. No.: US 2024/0007065 A1
(43) Pub. Date: Jan. 4, 2024

(54) POWER AMPLIFIER CIRCUIT, RADIO FREQUENCY CHIP AND ELECTRONIC DEVICE

(71) Applicant: SMARTER MICROELECTRONICS (GUANG ZHOU) CO., LTD., Guangzhou (CN)

(72) Inventors: Huadong WEN, Guangzhou (CN); Yang HOU, Guangzhou (CN)

(73) Assignee: SMARTER MICROELECTRONICS (GUANG ZHOU) CO., LTD., Guangzhou (CN)

(21) Appl. No.: 18/467,479

(22) Filed: Sep. 14, 2023

Related U.S. Application Data
(63) Continuation of application No. PCT/CN2022/128042, filed on Oct. 27, 2022.

(30) Foreign Application Priority Data
Oct. 27, 2021 (CN) 202111256020.1

(51) Int. Cl. H03F 3/24; H03F 3/72; H03F 1/56

(52) U.S. Cl. CPC H03F 3/245; H03F 3/72; H03F 1/56; H03F 2200/451; H03F 2200/411; H03F 2203/7236

(57) ABSTRACT

A power amplifier circuit includes N-stage power amplifiers connected in series, provided with an input end receiving a RF input signal and an output end outputting a RF output signal. In the N-stage power amplifiers, an output end of N-M stage power amplifiers and an output end of a final stage amplifier are grounded through their respective frequency doubling suppression circuits which are configured to suppress frequency doubling of the N-stage power amplifiers during operation, and N is an integer greater than or equal to 2.

### CROSS-REFERENCE TO RELATED APPLICATIONS

This is a continuation of International Application No. PCT/CN2022/128042 filed on 2022 Oct. 27, which claims priority to Chinese Patent Application No. 202111256020.1 filed on Oct. 27, 2021. The disclosures of the above-referenced applications are hereby incorporated by reference in their entirety.

### BACKGROUND

Compared with a previous Long Term Evolution (LTE) network, data transmission rate of a New Radio (NR) network is higher. Accordingly, requirements of linearity of a power amplifier correspondingly used for NR are higher.

### SUMMARY

Embodiments of the disclosure relate to, but are not limited to, the technical field of antennas, and in particular to a power amplifier circuit, a radio frequency (RF) chip and an electronic device.

The embodiments of the disclosure provide a power amplifier circuit, a RF chip and an electronic device.

According to a first aspect, there is provided a power amplifier circuit, including N-stage power amplifiers connected in series.

The N-stage power amplifiers are provided with an input end receiving a RF input signal and an output end outputting a RF output signal.

In the N-stage power amplifiers, an output end of N-M stage power amplifiers and an output end of a final stage amplifier are grounded through their respective frequency doubling suppression circuits which are configured to suppress frequency doubling of the N-stage power amplifiers during operation.

N is an integer greater than or equal to 2.

In some embodiments, the frequency doubling suppression circuit may include a trap circuit.

In some embodiments, the frequency doubling suppression circuit may include at least one of a double frequency suppression circuit, a triple frequency suppression circuit, or a quadruple frequency suppression circuit.

In some embodiments, an output end of each stage amplifier in the N-stage power amplifiers may be connected to at least one of the frequency doubling suppression circuits.

Or, output ends of part of amplifiers in the N-stage power amplifiers may be connected to at least one of the frequency doubling suppression circuits.

In some embodiments, output ends of last two stage amplifiers in the N-stage power amplifiers may be connected to the frequency doubling suppression circuits respectively.

In some embodiments, frequency doubling suppression circuits connected to output ends of at least two stage power amplifiers may have the same structure.

Or, part of the frequency doubling suppression circuits connected to output ends of at least two stage power amplifiers may have the same structure.

Or, the frequency doubling suppression circuits connected to output ends of at least two stage power amplifiers may have different structures.

In some embodiments, each of the frequency doubling suppression circuits may include at least an inductor-capacitor (LC) series circuit or an LC parallel circuit.

In some embodiments, a resonant frequency of at least one of frequency doubling suppression circuits connected to at least two stage power amplifiers may be adjustable.

In some embodiments, the frequency doubling suppression circuit with adjustable resonant frequency may include multiple parallel branches.

An end of each of multiple parallel branches is connected to the output end of the N-M stage power amplifiers in the N-stage power amplifiers, and another of each of multiple parallel branches is grounded, and N-M is an integer greater than or equal to 1.

The frequency doubling suppression circuit is adjusted by turning on or off multiple parallel branches.

In some embodiments, the frequency doubling suppression circuit with adjustable resonant frequency may further include an inductor.

Each of multiple parallel branches includes at least one capacitor provided with a first end connected to the output end of the N-M stage power amplifiers and a second end connected to a first end of the inductor.

A second end of the inductor is grounded.

In some embodiments, the frequency doubling suppression circuit with adjustable resonant frequency may further include a control switch.

The control switch is a single-pole multi-throw switch, and is provided with multiple first ends connected to the second end of the at least one capacitor, and a second end connected to the first end of the inductor.

According to a second aspect, there is provided a RF chip, including the power amplifier circuit according to any one of the above contents.

According to a third aspect, there is provided an electronic device, including the power amplifier circuit according to any one of the above contents, or the RF chip as described above.

In the embodiments of the disclosure, since in the N-stage power amplifiers connected in series, the output end of N-M stage power amplifiers and the output end of the final stage amplifier are grounded through their respective frequency doubling suppression circuits which are configured to suppress frequency doubling of the N-stage power amplifiers during operation, frequency doubling of the N-M stage power amplifiers and the final stage amplifier during operation are suppressed through the frequency doubling suppression circuits. Therefore, nonlinearity of the power amplifier may be reduced.

### BRIEF DESCRIPTION OF THE DRAWINGS

In order to explain technical solutions of the embodiments of the disclosure more clearly, drawings required to be used in the embodiments or descriptions of the related art will be briefly introduced below. It is apparent that drawings in the following descriptions are only some embodiments of the disclosure. Other drawings may also be obtained by those of ordinary skill in the art from these drawings without paying any creative work.

FIG. 1 shows a schematic structural diagram of a power amplifier circuit.

FIG. 2 shows a schematic diagram of relationship between an input spectrum and an output spectrum of a drive stage, and an output spectrum of an output stage in a power amplifier circuit.

FIG. 3 is a schematic structural diagram of a power amplifier circuit according to an embodiment of the disclosure.

FIG. 4 is a schematic structural diagram of another power amplifier according to an embodiment of the disclosure.

FIG. 5 is a schematic structural diagram of a RF chip according to an embodiment of the disclosure.

FIG. 6 is a schematic structural diagram of an electronic device according to an embodiment of the disclosure.

### DETAILED DESCRIPTION

Technical solutions of the disclosure will be described in detail below through embodiments and in combination with the drawings. The following specific embodiments may be combined with each other. The same or similar concepts or processes may not be repeated in some embodiments.

It should be noted that in examples of the disclosure, “first”, “second”, or the like are intended to distinguish similar objects, and are not necessarily intended to describe a specific order or sequence.

Furthermore, the technical solutions recited in the embodiments of the disclosure may be combined arbitrarily without conflict.

In an electronic device, a power amplifier (also known as a RF power amplifier) is one of essential components. The power amplifier is responsible for amplifying a modulated signal processed by a baseband chip and then feeding it to an antenna, to ensure that an electromagnetic wave radiated from the antenna has sufficient energy.

The inventors of the present disclosure have recognized that during design of the power amplifier, how to reduce nonlinearity of the power amplifier is a problem of concern.

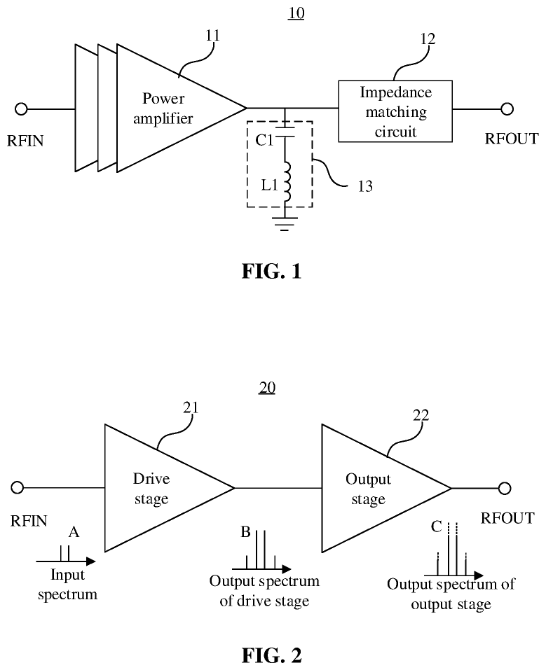

FIG. 1 shows a schematic structural diagram of a power amplifier circuit. As described in FIG. 1, the power amplifier circuit 10 includes multi-stage power amplifiers 11. An input end of the multi-stage power amplifiers 11 may receive a RF input signal (RFIN), and an output end of the multi-stage power amplifiers 11 may output a RF output signal (RFOUT) through an impedance matching circuit 12. The output end of the multi-stage power amplifiers 11 may also be grounded through a trap circuit 13.

In the embodiment shown in FIG. 1, since the trap circuit 13 is connected at the output end of the multi-stage power amplifiers 11, suppression of second harmonics of the power amplifier circuit depends on the trap circuit 13 connected to the output end of the multi-stage power amplifiers 11.

FIG. 2 shows a schematic diagram of relationship between an input spectrum and an output spectrum of a drive stage, and an output spectrum of an output stage in a power amplifier circuit. As shown in FIG. 2, in the power amplifier circuit 20, in case that a RF input signal (RFIN) is input to a drive stage 21 and an input spectrum of this signal is A, the input spectrum may not only be amplified, but also generate a second harmonic component through the drive stage 21. An output spectrum of a signal output by the drive stage 21 is B. It may be seen that the output spectrum of the drive stage 21 includes not only two harmonic components amplifying the input spectrum A (two components at the middle of the output spectrum of the drive stage), but also two second harmonic components generated by the drive stage 21 (two components on both sides of the output spectrum of the drive stage). After inputting the signal output by the drive stage 21 to an output stage 22, an output spectrum of a RF output signal (RFOUT) output by the output stage 22 is C. It may be seen that the output spectrum of the output stage includes not only two harmonic components amplifying a first harmonic in the output spectrum B (two components at the middle of the output spectrum of the output stage), but also two second harmonic components generated by the output stage 22. The two second harmonic components generated by the output stage 22 may be superimposed on the two second harmonic components generated by the drive stage 21 (such as two components on both sides of the output spectrum of the output stage).

Therefore, in case that the power amplifier circuit 20 is a multi-stage cascade structure, the second harmonic components generated by the drive stage 21 will be transmitted to the output stage 22. Therefore, in case that second harmonics in the power amplifier circuit 20 are required to be suppressed more effectively, performing second harmonic suppression at the output end of the multi-stage amplifier only cannot meet the requirements.

Based on the above problems, in some embodiments of the disclosure, the power amplifier circuit includes N-stage power amplifiers connected in series. The N-stage power amplifiers are provided with an input end receiving a RF input signal (RFIN) and an output end outputting a RF output signal (RFOUT). In the N-stage power amplifiers, an output end of N-M stage power amplifiers and an output end of a final stage amplifier are grounded through their respective frequency doubling suppression circuits which are configured to suppress frequency doubling of the N-stage power amplifiers during operation. N is an integer greater than or equal to 2, and N-M is an integer greater than or equal to 1. For example, N-M is equal to 1, 2, 3 or 4, or the like. In some embodiments, N-M may be an integer greater than or equal to 2; or, N-M may be an integer greater than or equal to 3, or the like.

In an embodiment, in the N-stage power amplifiers, the output end of N-M stage power amplifiers and the output end of the final stage amplifier are grounded through their respective frequency doubling suppression circuits. Exemplarily, in the N-stage power amplifiers, as to the output end of N-M stage power amplifiers and the output end of the final stage amplifier, the output end of each amplifier is grounded through a respective frequency doubling suppression circuit. In this kind of embodiments, the N-M stage power amplifiers may not include the final stage amplifier.

In some embodiments, in the N-stage power amplifiers, the output end of the N-M stage power amplifiers is grounded through the frequency doubling suppression circuit. Exemplarily, in the N-stage power amplifiers, as to the output end of N-M stage power amplifiers, the output end of each amplifier is grounded through a respective frequency doubling suppression circuit.

In an embodiment, in the N-stage power amplifiers, the output end of the final stage amplifier is grounded through the frequency doubling suppression circuit.

In an embodiment, the N-M stage power amplifiers may be the front N-M stage power amplifiers in the N-stage power amplifiers, or the rear N-M stage power amplifiers in the N-stage power amplifiers, or N-M stage power amplifiers at the middle of the N-stage power amplifiers, or N-M stage power amplifiers arranged at intervals in the N-stage power amplifiers.

In an embodiment, the N-M stage power amplifiers may be continuous N-M stage power amplifiers or discontinuous N-M stage power amplifiers. Exemplarily, the N-M stage power amplifiers may include odd stage power amplifiers in the N-stage power amplifiers; or, the N-M stage power amplifiers may include even stage power amplifiers in the N-stage power amplifiers.

On this basis, in some embodiments, the power amplifier circuit provided in the embodiments of the disclosure is not only connected to the frequency doubling suppression circuit at the output end of the final stage amplifier, but also connected to the frequency doubling suppression circuit at an output end of at least one of other stage amplifiers, so that harmonics in the power amplifier circuit may be effectively suppressed. Furthermore, since the output end of N-M stage amplifiers is connected to the frequency doubling suppression circuit, an input signal of a next stage amplifier may be rectified while power is increased, thereby a bias point of the amplifier may be improved and linearity of the power amplifier may be improved.

In the embodiments of the disclosure, since in the N-stage power amplifiers connected in series, the output end of N-M stage power amplifiers and the output end of the final stage amplifier are grounded through their respective frequency doubling suppression circuits which are configured to suppress frequency doubling of the N-stage power amplifiers during operation, frequency doubling of the N-M stage power amplifiers and the final stage amplifier during operation are suppressed through the frequency doubling suppression circuits. Therefore, nonlinearity of the power amplifier may be reduced.

In some embodiments, an output end of each stage amplifier in the N-stage power amplifiers is connected to a respective frequency doubling suppression circuit.

In some embodiments, an output end of each stage amplifier in the N-stage power amplifiers is connected to at least one of the frequency doubling suppression circuits.

In some embodiments, in the N-stage power amplifiers, output ends of part of amplifiers are connected to their respective frequency doubling suppression circuits, while output ends of part of amplifiers are not connected to the frequency doubling suppression circuits.

In some embodiments, output ends of part of amplifiers in the N-stage power amplifiers are connected to at least one of the frequency doubling suppression circuits.

In some embodiments, multiple frequency doubling suppression circuits of the power amplifier may have the same structure; or, part of multiple frequency doubling suppression circuits may have the same structure; or, multiple frequency doubling suppression circuits may have different structures.

In some embodiments, frequency doubling suppression circuits connected to output ends of at least two stage power amplifiers have the same structure. In some other embodiments, part of the frequency doubling suppression circuits connected to output ends of at least two stage power amplifiers have the same structure. In still other embodiments, the frequency doubling suppression circuits connected to output ends of at least two stage power amplifiers have different structures.

In any one of the embodiments of the disclosure, the at least two stage power amplifiers may be at least two stage power amplifiers in the N-stage power amplifiers, or at least two stage power amplifiers in the N-M stage power amplifiers and the final stage amplifier.

In some embodiments, the frequency doubling suppression circuits having the same structures may include at least one of following aspects in the frequency doubling suppression circuits being the same: electronic elements are the same, connection structures of the electronic elements are the same, or parameter values of the electronic elements are the same. In some embodiments, the frequency doubling suppression circuits having different structures may include at least one of following aspects in the frequency doubling suppression circuits being different: electronic elements are different, connection structures of the electronic elements are different, or parameter values of the electronic elements are different.

In some embodiments, the frequency doubling suppression circuit may be an LC series circuit, an LC parallel circuit, another circuit which may generate a resonant frequency, or a combination of the above circuit structures. For example, the frequency doubling suppression circuit includes at least an LC series circuit or an LC parallel circuit.

In some embodiments, the frequency doubling suppression circuit includes at least one of a double frequency suppression circuit, a triple frequency suppression circuit, or a quadruple frequency suppression circuit.

In some embodiments, the frequency doubling suppression circuit includes the double frequency suppression circuit which is configured to suppress a double frequency, that is, a second harmonic. In other embodiments, the frequency doubling suppression circuit may also be configured to suppress other frequency doubling signals, such as at least one of quadruple frequency, sixfold frequency, triple frequency, quintuple frequency, or the like, that is, the frequency doubling suppression circuit may further include a quadruple frequency suppression circuit, a sixfold frequency suppression circuit, a triple frequency suppression circuit, a quintuple frequency suppression circuit, or the like.

It should be noted that frequency doubling suppressed by multiple frequency doubling suppression circuits may be all the same, partially the same, or all different.

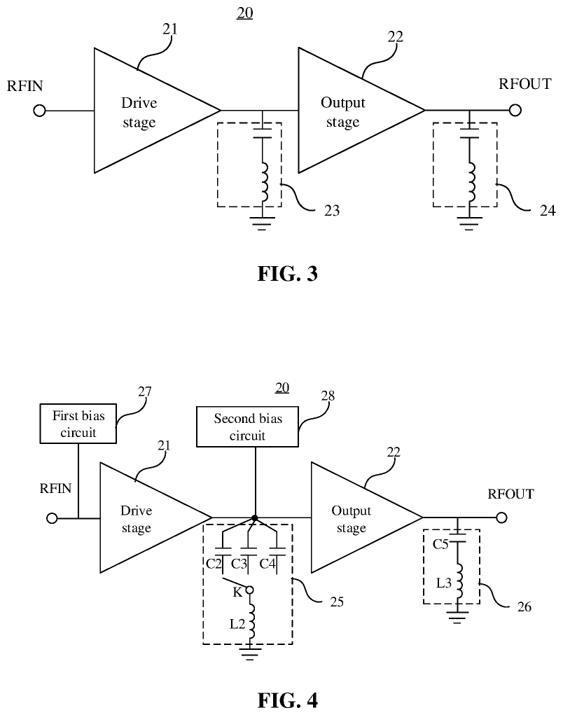

FIG. 3 is a schematic structural diagram of a power amplifier circuit according to an embodiment of the disclosure. In the embodiment shown in FIG. 3, in case that the N-stage power amplifiers connected in series include a drive stage 21 and an output stage 22 connected in series, N is equal to 2. An output end of the drive stage 21 may be grounded through a first frequency doubling suppression circuit 23, and an output end of the output stage 22 may be grounded through a second frequency doubling suppression circuit 24. Here, the first frequency doubling suppression circuit 23 and the second frequency doubling suppression circuit 24 may be the same or different circuit structures. For example, at least one of the first frequency doubling suppression circuit 23 or the second frequency doubling suppression circuit 24 may be an LC series circuit, an LC parallel circuit, or another circuit which may generate a resonant frequency.

Resonant frequencies of the first frequency doubling suppression circuit 23 and the second frequency doubling suppression circuit 24 may be the same or different. The resonant frequencies of the first frequency doubling suppression circuit 23 and the second frequency doubling suppression circuit 24 may be within multiple of an operation frequency range of the power amplifier circuit 20. For example, in case that the frequency doubling suppression circuits (including the first frequency doubling suppression circuit 23 and the second frequency doubling suppression circuit 24) are configured to suppress a double frequency of the power amplifier circuit 20, and the operation frequency range of the power amplifier circuit 20 is 3.3 GHz to 4.2 GHz, the resonant frequencies of the frequency doubling suppression circuits may be within 6.6 GHz to 8.4 GHz.

In some other embodiments, the N-stage power amplifiers connected in series may further include three-stage power amplifiers connected in series, four-stage power amplifiers connected in series, or the like. The number of N is not limited in the embodiments of the disclosure.

In case that the N-stage power amplifiers connected in series include three-stage power amplifiers connected in series, a value of N-M may be 2 or 3. In some embodiments, in case that the value of N-M is 2, output ends of last two stage power amplifiers in the three-stage power amplifiers are grounded through two frequency doubling suppression circuits respectively. In some embodiments, in case that the value of N-M is 3, an output end of each stage power amplifier in the three-stage power amplifiers is grounded through each respective frequency doubling suppression circuit respectively.

In case that the N-stage power amplifiers connected in series include four-stage power amplifiers connected in series, a value of N-M may be 2 or 3 or 4. In some embodiments, in case that the value of N-M is 2, output ends of last two stage power amplifiers in the four-stage power amplifiers are grounded through their respective frequency doubling suppression circuits respectively. In some embodiments, in case that the value of N-M is 3, output ends of last three stage power amplifiers in the four-stage power amplifiers are grounded through their respective frequency doubling suppression circuits respectively. In some embodiments, in case that the value of N-M is 4, an output end of each stage power amplifier in the four-stage power amplifiers is grounded through a respective frequency doubling suppression circuit respectively.

In some embodiments, frequency doubling suppression capabilities of multiple frequency doubling suppression circuits may be set from low to high. For example, frequency doubling suppression capability of a frequency doubling suppression circuit connected to an output end of a last stage power amplifier is the highest. Frequency doubling suppression capability of a frequency doubling suppression circuit connected to an output end of a penultimate stage power amplifier is less than the frequency doubling suppression capability of the frequency doubling suppression circuit connected to the output end of the last stage power amplifier. Frequency doubling suppression capability of a frequency doubling suppression circuit connected to an output end of an antepenult stage power amplifier is less than the frequency doubling suppression capability of the frequency doubling suppression circuit connected to the output end of the penultimate stage power amplifier, or the like.

In some other embodiments, frequency doubling suppression capabilities of multiple frequency doubling suppression circuits may be set from high to low.

In still other embodiments, frequency doubling suppression capabilities of multiple frequency doubling suppression circuits may be the same.

In some embodiments, multiple frequency doubling suppression circuits have the same circuit structure. In some other embodiments, multiple frequency doubling suppression circuits have different circuit structures. When frequency doubling suppression capability of a frequency doubling suppression circuit is relatively high, a number of capacitors and/or inductors in the frequency doubling suppression circuit is relatively large; and when frequency doubling suppression capability of a frequency doubling suppression circuit is relatively low, a number of capacitors in the frequency doubling suppression circuit is relatively large, and/or a number of inductors in the frequency doubling suppression circuit is relatively small.

In an embodiment, output ends of last two stage amplifiers in the N-stage power amplifiers are connected to the frequency doubling suppression circuits.

In some embodiments, N may be an integer greater than or equal to 3, that is, the power amplifier circuit includes at least three stage power amplifiers connected in series. No matter what value taken by N, last two stage amplifiers are connected to the frequency doubling suppression circuits. In this way, only the output end of each of the last two stage power amplifiers is grounded through the frequency doubling suppression circuit, which may not only suppress frequency doubling of the power amplifier circuit during operation, but also reduce the number of frequency doubling suppression circuits set in the power amplifier circuit and reduce cost of manufacturing the power amplifier circuit.

In some embodiments, frequency doubling suppression capability of the frequency doubling suppression circuit connected to the output end of each of the last two stage power amplifiers may be the same. In some other embodiments, doubling suppression capability of the frequency doubling suppression circuit connected to the output end of the last stage power amplifier is greater than frequency doubling suppression capability of the frequency doubling suppression circuit connected to the output end of the penultimate stage power amplifier.

In some embodiments, the frequency doubling suppression circuit connected to the output end of each of the last two stage power amplifiers has the same or different structures.

In case that the power amplifiers in the power amplifier circuit or the N-stage power amplifiers connected in series are not connected to the frequency doubling suppression circuits, when the power amplifier circuit operates in a relatively large bandwidth, the power amplifier circuit may generate more double frequencies, thus increasing nonlinearity of the power amplifier. However, in the embodiments of the disclosure, it may enable the power amplifier circuit to operate in a wider band and to be optimized for each frequency point, to ensure optimization of broadband performance.

The frequency doubling suppression circuit includes a trap circuit. In an embodiment of the disclosure, the trap circuit may include an LC series circuit. In other embodiments, the trap circuit may include an LC parallel circuit, or other LC circuits, or the like.

In some embodiments, a resonant frequency of at least one of multiple frequency doubling suppression circuits is adjustable. In some implementations, a resonant frequency of at least one of frequency doubling suppression circuits connected to at least two stage power amplifiers is adjustable.

The resonant frequency of the frequency doubling suppression circuit may be adjusted by changing a capacitance value of a capacitor in the frequency doubling suppression circuit; or, the resonant frequency of the frequency doubling suppression circuit may be adjusted by changing an inductance value of an inductor in the frequency doubling suppression circuit; or, the resonant frequency of the frequency doubling suppression circuit may be adjusted by changing the capacitance value of the capacitor and the inductance value of the inductor in the frequency doubling suppression circuit.

In some embodiments, resonant frequencies of different frequency doubling suppression circuits are adjusted in the same or different ways. Exemplarily, resonant frequencies of at least a part of multiple frequency doubling suppression circuits are adjusted by adjusting capacitance values and/or inductance values, and/or resonant frequencies of at least a part of multiple frequency doubling suppression circuits are adjusted by disconnecting connection of at least one capacitor and/or at least one inductor.

In an embodiment, the frequency doubling suppression circuit with adjustable resonant frequency includes multiple parallel branches.

An end of each of multiple parallel branches is connected to the output end of the N-M stage power amplifiers in the N-stage power amplifiers, and another of each of multiple parallel branches is grounded, and N-M is an integer greater than or equal to 1.

The frequency doubling suppression circuit is adjusted by turning on or off multiple parallel branches.

For example, the output end of the N-M stage power amplifiers is connected to N-M frequency doubling suppression circuits respectively. A target frequency doubling suppression circuit with adjustable resonant frequency (that is, any one frequency doubling suppression circuit with adjustable resonant frequency in the N-M frequency doubling suppression circuits) may include multiple parallel branches. An end of each of multiple parallel branches is connected to an output end of the target frequency doubling suppression circuit, and another of each of multiple parallel branches is grounded.

In an embodiment, the frequency doubling suppression circuit with adjustable resonant frequency further includes an inductor.

Each of multiple parallel branches includes at least one capacitor provided with a first end connected to the output end of the N-M stage power amplifiers and a second end connected to a first end of the inductor.

A second end of the inductor is grounded.

In some other embodiments, the parallel branch may further include resistors and/or other electronic elements, which are not limited in the embodiments of the disclosure.

In an embodiment, the frequency doubling suppression circuit with adjustable resonant frequency further includes a control switch.

The control switch is a single-pole multi-throw switch, and is provided with multiple first ends connected to the second end of the at least one capacitor, and a second end connected to the first end of the inductor.

In some embodiments, in case that a parallel branch includes multiple capacitors, multiple first ends of the control switch may be connected to or disconnected from a second end of each of multiple capacitors, or multiple first ends of the control switch may be connected to or disconnected from a second end of a capacitor close to the inductor among multiple capacitors.

In the embodiments of the disclosure, the single-pole multiple-throw switch is connected to or disconnected from capacitors in each of multiple parallel branches, so that adjustment of the resonant frequency by turning on or off capacitors in each of multiple parallel branches may be achieved.

In some embodiments, the control switch may be connected to a processor of an electronic device, to enable the processor to control on or off of the control switch. In some embodiments, the control switch may include multiple Metal-Oxide-Semiconductor Field-Effect Transistor (MOSFET/MOS) switches. The processor controls on or off of each of the MOS switches, connection or disconnection between the control switch and each capacitor may be achieved.

An implementation of adjusting a resonant frequency of a frequency doubling suppression circuit by changing capacitance values of capacitors in a frequency doubling suppression circuit is described below.

The frequency doubling suppression circuit includes a control switch, an inductor and multiple capacitors. The output end of each stage power amplifier in the N-M stage power amplifiers is connected to a first end of each of multiple capacitors respectively. A second end of each of multiple capacitors is connected to a first end of the control switch. A second end of the control switch is connected to a first end of the inductor, and a second end of the inductor is grounded. Here, the control switch is configured to control at least one of multiple capacitors and the inductor to be turned on.

The number of capacitors in multiple capacitors may be an integer greater than or equal to 2. For example, the number of capacitors in multiple capacitors may be 2, 3, 4 or 5, or the like. Capacitance values of multiple capacitors are different. The number of capacitors in multiple capacitors is not limited in the embodiments of the disclosure. In case that the more the number of capacitors in multiple capacitors is, the resonant frequency of the frequency doubling suppression circuit is closer to a double frequency of a current operation frequency of the power amplifier circuit by turning on the selected at least one capacitor and the inductor, so that a suppression effect of the double frequency in the power amplifier circuit is better. In case that the less the number of capacitors in multiple capacitors is, complexity of the power amplifier circuit may be reduced and cost of manufacturing the power amplifier circuit may be reduced.

In some other embodiments, the frequency doubling suppression circuit includes a control switch, a capacitor and multiple inductors. The output end of each stage power amplifier in the N-M stage power amplifiers is connected to a first end of each of multiple inductors respectively. A second end of each of multiple inductors is connected to a first end of the control switch. A second end of the control switch is connected to a first end of the capacitor, and a second end of the capacitor is grounded. Here, the control switch is configured to control at least one of multiple inductors and the capacitor to be turned on.

The number of inductors in multiple inductors may be an integer greater than or equal to 2. For example, the number of inductors in multiple inductors may be 2, 3, 4 or 5, or the like. Inductance values of multiple inductors are different. The number of inductors in multiple inductors is not limited in the embodiments of the disclosure.

In some embodiments, the number of capacitors in multiple capacitors may be determined based on bandwidth of an operation frequency range of the power amplifier circuit. In case that the wider the bandwidth of the frequency range is, the more the number of capacitors in multiple capacitors is, and in case that the narrower the bandwidth of the frequency range is, the less the number of capacitors in multiple capacitors is.

The control switch may be a single-pole multi-throw switch, so that at least one of multiple capacitors and the inductor are controlled to be turned on through an action of the single-pole multi-throw switch. In some other embodiments, the control switch may be an integrated switch or an integrated circuit. In still other embodiments, the control switch may include an N-channel metal oxide semiconductor (NMOS) switch or a P-channel metal oxide semiconductor (PMOS) switch.

A frequency doubling suppression circuit including multiple capacitors, and a method of adjusting resonant frequency of the frequency doubling suppression circuit by controlling different capacitors to be turned on, are described as above. In some other embodiments, the frequency doubling suppression circuit may include a capacitor and multiple inductors, and the resonant frequency of the frequency doubling suppression circuit may be adjusted by controlling different inductors to be turned on. For example, the output end of each stage power amplifier in the N-M stage power amplifiers is connected to a first end of each of multiple inductors respectively. A second end of each of multiple inductors is connected to a first end of the control switch. A second end of the control switch is connected to a first end of the capacitor, and a second end of the capacitor is grounded.

In some embodiments, a third end of the control switch is connected to a processing circuit. The processing circuit is configured to output a control signal to the control switch based on an operation frequency range of the N-stage power amplifiers, and the control signal is used by the control switch to control the at least one capacitor and the inductor to be turned on.

In some other embodiments, a processor may determine side information of at least one of channel quality, Reference Signal Receiving Power (RSRP), path loss, uplink and downlink service requirements, or the like corresponding to the operation frequency range of the N-stage power amplifiers, and then output a control signal to the control switch based on the side information and the operation frequency range of the N-stage power amplifiers. For example, in case that the channel quality is relatively low, RSRP is relatively low, the path loss is relatively high, and uplink and downlink services are relatively important, a capacitor with relatively large capacitance value and the inductor may be controlled to be turned on, so as to improve frequency doubling suppression capability of the frequency doubling suppression circuit.

The processing circuit may be a processor or a power management chip in an electronic device. The processor or power management chip may include integration of any one or more of: an Application Specific Integrated Circuit (ASIC), a Digital Signal Processor (DSP), a Digital Signal Processing Device (DSPD), a Programmable Logic Device (PLD), a Field Programmable Gate Array (FPGA), a Central Processing Unit (CPU), a Graphics Processing Unit (GPU), an embedded Neural-network Processing Unit (NPU), a controller, a microcontroller, and a microprocessor. It may be understood that the electronic device implementing the above processor functions may also be another device, which is not specifically limited in the embodiments of the disclosure.

In some embodiments, the control signal may indicate a target capacitor or a target inductor which is turned on, so that in case that the target capacitor or the target inductor is turned on, the resonance frequency of the frequency doubling suppression circuit is within a double frequency range of the operation frequency range of the N-stage power amplifiers.

The number of capacitors in multiple capacitors being 3, and the operation frequency range of the power amplifier being 3.3 GHz to 4.2 GHz are taken as an example: when the processing circuit determines that the current operation frequency of the power amplifier is between 3.3 GHz and 3.6 GHz, then a double frequency of 3.3 GHz to 3.6 GHz is determined to be 6.6 GHz to 7.2 GHz, a first capacitor of the three capacitors may be controlled to be turned on, so that the resonance frequency of the frequency doubling suppression circuit is between 6.6 GHz and 7.2 GHz; when the processing circuit determines that the current operation frequency of the power amplifier is between 3.6 GHz and 3.8 GHz, then a double frequency of 3.6 GHz to 3.8 GHz is determined to be 7.2 GHz to 7.6 GHz, a second capacitor of the three capacitors may be controlled to be turned on, so that the resonance frequency of the frequency doubling suppression circuit is between 7.2 GHz and 7.6 GHz; when the processing circuit determines that the current operation frequency of the power amplifier is between 3.8 GHz and 4.2 GHz, then a double frequency of 3.8 GHz to 4.2 GHz is determined to be 7.6 GHz to 8.4 GHz, a third capacitor of the three capacitors may be controlled to be turned on, so that the resonance frequency of the frequency doubling suppression circuit is between 7.6 GHz and 8.4 GHz.

An implementation of adjusting a resonant frequency of a frequency doubling suppression circuit by changing capacitance values of capacitors in a certain frequency doubling suppression circuit is described below.

FIG. 4 is a schematic structural diagram of another power amplifier according to an embodiment of the disclosure. As shown in FIG. 4, the N-stage power amplifiers connected in series include a drive stage 21 and an output stage 22 connected in series. An output end of the drive stage 21 may be grounded through a third frequency doubling suppression circuit 25, and an output end of the output stage 22 may be grounded through a fourth frequency doubling suppression circuit 26.

The third frequency doubling suppression circuit 25 includes a first capacitor C2, a second capacitor C3, a third capacitor C4, a control switch K and a first inductor L2. The output end of the drive stage 21 is connected to first ends of the first capacitor C2, the second capacitor C3 and the third capacitor C4 respectively. Second ends of the first capacitor C2, the second capacitor C3 and the third capacitor C4 may be all connected to a first end of the control switch K. A second end of the control switch K is connected to a first end of the first inductor L2, and a second end of the first inductor L2 is grounded.

The fourth frequency doubling suppression circuit 26 includes a fourth capacitor C5 and a second inductor L3. The output end of the output stage 22 is connected to a first end of the fourth capacitor C5, a second end of the fourth capacitor C5 is connected to a first end of the second inductor L3, and a second end of the second inductor L3 is grounded.

Although FIG. 4 shows that the resonant frequency of the frequency doubling suppression circuit connected to the output end of the drive stage 21 is set to be adjustable, the embodiments of the disclosure are not limited thereto. In other embodiments, the resonant frequency of the frequency doubling suppression circuit connected to the output end of the drive stage 21 may be set to be non-adjustable, while the resonant frequency of the frequency doubling suppression circuit connected to the output end of the output stage 22 is set to be adjustable. For example, the output end of the drive stage 21 is connected to the fourth frequency doubling suppression circuit 26, and the output end of the output stage 22 is connected to the third frequency doubling suppression circuit 25. Or, the resonant frequency of the frequency doubling suppression circuit connected to the output end of the drive stage 21 and the resonant frequency of the frequency doubling suppression circuit connected to the output end of the output stage 22 may be all set to be adjustable. For example, the output end of the drive stage 21 is connected to a third frequency doubling suppression circuit 25, and the output end of the output stage 22 is connected to another third frequency doubling suppression circuit 25. Furthermore, the resonant frequency of the frequency doubling suppression circuit may be implemented by turning on different capacitors or turning on different inductors.

In some embodiments, an input end of each of at least one power amplifier in the N-stage power amplifiers is connected to a bias circuit, and the bias circuit is configured to provide a bias voltage to each connected power amplifier.

In the embodiments corresponding to FIG. 3 and FIG. 4, the input end of the drive stage 21 may be a base of the drive stage 21; the output end of the drive stage 21 connected to the output stage may be a collector of the drive stage 21; one end of the drive stage 21 connected to the first frequency doubling suppression circuit 23, or one end of the drive stage 21 connected to the third frequency doubling suppression circuit is an emitter or source of the drive stage 21. The input end of the output stage 22 may be a base of the output stage 22; the output end of the output stage 22 outputting a RF output signal may be a collector of the output stage 22; one end of the output stage 22 connected to the second frequency doubling suppression circuit 24, or one end of the output stage 22 connected to the fourth frequency doubling suppression circuit 26, is an emitter or source of the output stage 22.

Still referring to FIG. 4, the input end of the drive stage 21 may be connected to a first bias circuit 27 configured to provide a first bias voltage to the drive stage 21, and the input end of the output stage 22 may be connected to a second bias circuit 28 configured to provide a second bias voltage to the output stage 22.

In some embodiments, the N-stage power amplifiers output the RF output signal through an output impedance matching circuit, and/or the N-stage power amplifiers receive the RF input signal through an input impedance matching circuit.

For example, as shown in FIG. 4, the RF output signal may be output at the output end of the output stage 22 through an output impedance matching circuit. The embodiments of the disclosure are not limited thereto. In some other embodiments, the input end of the drive stage 21 may also receive the RF input signal through an input impedance matching circuit.

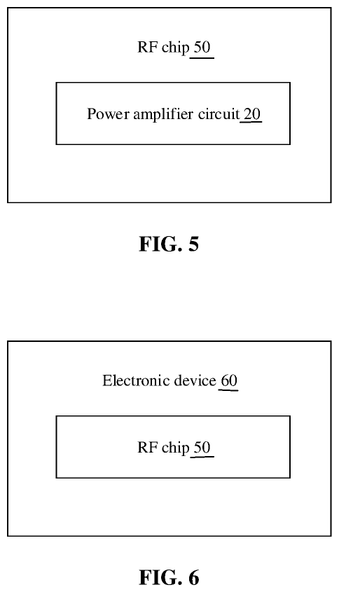

FIG. 5 is a schematic structural diagram of a RF chip according to an embodiment of the disclosure. As shown in FIG. 5, a RF chip 50 includes the power amplifier circuit 20 provided in any one of the above embodiments.

The RF chip 50 may further include at least one of an antenna switch, a filter, a duplexer or diplexer, a low noise amplifier (LNA), or the like.

FIG. 6 is a schematic structural diagram of an electronic device according to an embodiment of the disclosure. As shown in FIG. 6, an electronic device 60 includes the RF chip 50. In some other embodiments, the electronic device 60 includes the power amplifier circuit 20 provided in any one of the above embodiments.

In some embodiments, the electronic device may further include at least one of a baseband chip, a processor, a memory, or the like.

The electronic device may be one of a server, a mobile phone, a pad, a computer with wireless transceiver functions, a hand-held computer, a desktop computer, a personal digital assistant (PDA), a portable media player, a smart speaker, a navigation device, a smart watch, smart glasses, a smart necklace and another wearable device, a pedometer, a digital TV, a Virtual Reality (VR) terminal device, an Augmented Reality (AR) terminal device, a wireless terminal in Industrial Control, a wireless terminal in Self Driving, a wireless terminal in Remote Medical Surgery, a wireless terminal in Smart Grid, a wireless terminal in Transportation Safety, a wireless terminal in Smart City, a wireless terminal in Smart Home, or a vehicle, an on-board device, an on-board module, or the like in an Internet of Vehicles system.

It should be understood that reference to “one embodiment” or “an embodiment” or “an embodiment of the disclosure” or “the forgoing embodiments” or “some implementations” or “some embodiments” throughout the entire description means that specific features, structures or characteristics related to the embodiments are included in at least one embodiment of the disclosure. Therefore, words “in one embodiment” or “in an embodiment” or “an embodiment of the disclosure” or “the forgoing embodiments” or “some implementations” or “some embodiments” appearing throughout the entire description may not necessarily refer to the same embodiment. Furthermore, these specific features, structures or characteristics may be combined in one or more embodiments in any suitable way. It should be understood that in various embodiments of the disclosure, sizes of serial numbers of the above processes do not mean a sequence of execution thereof. Execution sequences of the processes should be determined by their functions and internal logics, and should not constitute any restriction on implementation of the embodiments of the disclosure. Serial numbers of the above embodiments of the disclosure are only intended for description and do not represent advantages or disadvantages of the embodiments.

Furthermore, terms “first” and “second” are only for the purpose of description, and cannot be understood as indicating or implying relative importance or implicitly indicating the number of indicated technical features. Therefore, features defined with “first” and “second” may explicitly or implicitly include one or more of said features. In descriptions of the disclosure, “multiple” means two or more, unless otherwise specified explicitly.

In descriptions of the disclosure, it should be noted that unless otherwise specified and limited explicitly, terms “install”, “link” and “connect” should be understood in a broad sense. For example, it may mean fixed connection, removable connection, or integrated connection; it may mean mechanical connection, electrical connection, or communication with each other; it may mean direct connection, or indirect connection through intermediate media, or it may mean internal connection of two elements or interaction between two elements. Specific meanings of the above terms in the disclosure may be understood by those of ordinary skill in the art according to a specific situation.

In the disclosure, unless otherwise specified and limited explicitly, a first feature “above” or “below” a second feature may include the first feature directly contacting the second feature, or may include the first feature contacting the second feature through other features there-between, rather than the first feature directly contacting the second feature. Furthermore, the first feature “above”, “on” and “atop” the second feature includes the first feature being directly above or diagonally above the second feature, or only indicates that a horizontal height of the first feature is higher than that of the second feature. The first feature “below”, “under” and “beneath” the second feature includes the first feature being directly below or diagonally below the second feature, or only indicates that a horizontal height of the first feature is lower than that of the second feature.

In several embodiments provided in the disclosure, it should be understood that the disclosed devices and circuits may be implemented by other means. The device embodiments as described above are only schematic. For example, division of the units is only a logical function division. There may be other division means in an actual implementation, for example, multiple units or components may be combined, or may be integrated into another system, or some features may be ignored, or may not be implemented. Furthermore, coupling, or direct coupling, or communication connection between components as shown or discussed may be indirect coupling or communication connection through some interfaces, devices or units, and may be electrical, mechanical or other forms.

The unit shown as a separate component may be or may not be physically separated, and the component shown as a unit may be or may not be a physical unit, and it may be located in one place or distributed to multiple network units; and some or all of the units may be selected according to actual requirements to achieve the purpose of solutions of the embodiments.

Features disclosed in several circuit embodiments provided in the disclosure may be combined arbitrarily without conflict, to obtain new circuit embodiments. Features disclosed in several product embodiments provided in the disclosure may be combined arbitrarily without conflict, to obtain new product embodiments. Features disclosed in several device embodiments provided in the disclosure may be combined arbitrarily without conflict, to obtain new device embodiments.

When implemented in form of a software function module and sold or used as an independent product, the above integrated unit of the disclosure may also be stored in a computer storage medium. Based on such understanding, the technical solutions of the embodiments of the disclosure substantially or parts making contributions to the related art may be embodied in form of a software product, and the computer software product is stored in a storage medium, including several instructions configured to enable a piece of computer device (which may be a personal computer, a server, a network device, or the like) to execute all or part of the methods described in the embodiments of the disclosure. The abovementioned storage medium includes various media which may store program codes, such as a removable storage device, a Read-Only Memory (ROM), a magnetic disk, an optical disk, or the like.

It is worth noting that the drawings in the embodiments of the disclosure are only intended to illustrate a schematic position of each device position, and do not represent a true position of each device with respect to each other. The true position of each device or each area may be correspondingly changed or offset according to an actual situation (for example, a structure of the terminal device), and proportions of different parts of the terminal device in the drawings do not represent true proportions.

“an”, “the” and “this” in a singular form used in the embodiments of the disclosure and the appended claims are also intended to include a plural form, unless the context clearly indicates other meanings.

It should be understood that term “and/or” used here is only an association relationship describing associated objects, and indicates that there may be three kinds of relationships. For example, A and/or B may indicate that there are three situations: presence of A alone, presence of A and B simultaneously, and presence of B alone. Furthermore, character “I” here generally indicates that associated objects before and after this character are in “or” relationship.

The above descriptions are only specific implementations of the disclosure, however, the scope of protection of the disclosure is not limited thereto. Any variations or replacements apparent to those skilled in the art within the technical scope disclosed in the disclosure should fall within the scope of protection of the disclosure. Therefore, the scope of protection of the disclosure should be subjected to the scope of protection of the claims.

The disclosure discloses a power amplifier circuit, a RF chip and an electronic device, in which N-stage power amplifiers are connected in series, provided with an input end receiving a RF input signal and an output end outputting a RF output signal; in the N-stage power amplifiers, an output end of N-M stage power amplifiers and an output end of a final stage amplifier are grounded through their respective frequency doubling suppression circuits which are configured to suppress frequency doubling of the N-stage power amplifiers during operation, and N is an integer greater than or equal to 2. With the solutions disclosed in the disclosure, nonlinearity of the power amplifier may be reduced.

What is claimed is:

1. A power amplifier circuit, comprising:
N-stage power amplifiers connected in series, provided with an input end receiving a radio frequency (RF) input signal and an output end outputting a RF output signal,
in the N-stage power amplifiers, an output end of N-M stage power amplifiers and an output end of a final stage amplifier being grounded through their respective frequency doubling suppression circuits which are configured to suppress frequency doubling of the N-stage power amplifiers during operation,
N being an integer greater than or equal to 2.

2. The power amplifier circuit of claim 1, wherein the frequency doubling suppression circuit comprises a trap circuit.

3. The power amplifier circuit of claim 1, wherein the frequency doubling suppression circuit comprises at least one of a double frequency suppression circuit, a triple frequency suppression circuit, or a quadruple frequency suppression circuit.

4. The power amplifier circuit of claim 1, wherein an output end of each stage amplifier in the N-stage power amplifiers is connected to at least one of the frequency doubling suppression circuits,
or, output ends of part of amplifiers in the N-stage power amplifiers are connected to at least one of the frequency doubling suppression circuits.

5. The power amplifier circuit of claim 1, wherein output ends of last two stage amplifiers in the N-stage power amplifiers are connected to the frequency doubling suppression circuits respectively.

6. The power amplifier circuit of claim 1, wherein frequency doubling suppression circuits connected to output ends of at least two stage power amplifiers have the same structure,
or, part of the frequency doubling suppression circuits connected to output ends of at least two stage power amplifiers have the same structure,
or, the frequency doubling suppression circuits connected to output ends of at least two stage power amplifiers have different structures.

7. The power amplifier circuit of claim 1, wherein each of the frequency doubling suppression circuits comprises at least an inductor-capacitor (LC) series circuit or an LC parallel circuit.

8. The power amplifier circuit of claim 1, wherein a resonant frequency of at least one of frequency doubling suppression circuits connected to at least two stage power amplifiers is adjustable.

9. The power amplifier circuit of claim 8, wherein the frequency doubling suppression circuit with adjustable resonant frequency comprises a plurality of parallel branches,
an end of each of the plurality of parallel branches is connected to the output end of the N-M stage power amplifiers in the N-stage power amplifiers, and another end of each of the plurality of parallel branches is grounded, and N-M is an integer greater than or equal to 1,
the frequency doubling suppression circuit is adjusted by turning on or off the plurality of parallel branches.

10. The power amplifier circuit of claim 9, wherein the frequency doubling suppression circuit with adjustable resonant frequency further comprises an inductor,
each of the plurality of parallel branches comprises at least one capacitor provided with a first end connected to the output end of the N-M stage power amplifiers and a second end connected to a first end of the inductor,
a second end of the inductor is grounded.

11. The power amplifier circuit of claim 10, wherein the frequency doubling suppression circuit with adjustable resonant frequency further comprises a control switch,
the control switch is a single-pole multi-throw switch, and is provided with a plurality of first ends connected to the second end of the at least one capacitor, and a second end connected to the first end of the inductor.

12. A radio frequency (RF) chip, comprising the power amplifier circuit of claim 1.

13. An electronic device, comprising the power amplifier circuit of claim 1, or the radio frequency (RF) chip.
